(19) United States
(12) Patent Application Publication
(10) Pub. No.: US 2010/0033407 A1
(43) Pub. Date: Feb. 11, 2010

(54) ORGANIC EL DISPLAY APPARATUS AND MANUFACTURE METHOD THEREOF

(76) Inventor: Chihiro Harada, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/450,332

(22) PCT Filed: Mar. 29, 2007
(86) PCT No.: PCT/JP2007/056856

§ 371 Date: Sep. 22, 2009

(51) Int. Cl. G09G 3/30; H01L 21/28

(52) U.S. Cl. 345/76; 438/29; 257/E21.158

(57) ABSTRACT

[Problems] To enhance production efficiency of an organic EL display apparatus active-driven with an organic EL element and an organic transistor.

[Solving Means] An organic EL display apparatus includes a plurality of dots (4), each of the dots (4) at least including an organic EL element (5), a capacitor (7), and an organic transistor (6), the display apparatus including a display portion formed of the dots (4) arranged on a substrate (3), and the display apparatus being active-driven, wherein, when the shortest interval between the organic transistors (6) in a channel length direction is represented as a, all of the organic transistors (6) provided for the display portion are placed such that each of intervals between the organic transistors in the channel length direction is equal to an integral multiple of the interval a.

### TECHNICAL FIELD

The present invention relates to an organic EL display apparatus including an organic EL element and an organic transistor, and a manufacture method thereof.

### BACKGROUND ART

Organic EL display apparatuses having organic EL elements which are a type of self-emission element have advantages over other display apparatuses including liquid crystal displays and plasma displays in that the former can achieve high image quality and wide viewing angles and can be manufactured at low cost.

The organic EL display apparatus has a display portion which is formed of pixels (each corresponding to one picture element) arranged in a matrix including numerous organic EL elements. One pixel may consist of a plurality of sub-pixels. In the present specification, the smallest unit of points constituting the display is referred to as a “dot.” Thus, the dot means the pixel in a monochrome display and means the sub-pixel in a color display. Driving schemes for the display portion are broadly grouped into two, that is, a passive matrix type and an active matrix type. Because of growing demand for increasingly larger screens in recent years, research and development work has been actively conducted on organic EL display apparatuses of the active matrix type which can be driven at a small current.

The organic EL display apparatus of the active matrix type has an organic EL element and organic transistors which are placed in each dot, and is controlled to hold a driving signal for a time period between frames, for example.

The abovementioned organic EL element is a self-emission element based on an electroluminescence phenomenon of an organic substance. The organic EL element includes an anode, an organic layer including a light-emitting layer, and a cathode, all of which are typically stacked over an upper surface of a transparent substrate. Holes and electrons injected through the anode and cathode are recombined in the organic layer to emit light.

The abovementioned organic transistor has basic principles similar to those of typical transistors. For example, an organic transistor of MOS-FET (metal oxide semiconductor field-effect transistor) structure has a gate electrode and an organic semiconductor layer which are formed with a gate insulating layer interposed therebetween, in which a voltage is applied to the gate electrode to form a channel in the organic semiconductor layer, thereby controlling an electric current between a source electrode and a drain electrode.

In recent years, to achieve a lower-cost process, it is contemplated that the organic semiconductor layer may be coated by using an organic material of low molecular weight such as a pentacene precursor or a polymer organic material such as polyalkylthiophene. If the coating application can be used for the film formation, the organic semiconductor layer can be manufactured through a simple process such as an inkjet printing method with less waste of material. It is also contemplated that not only the organic semiconductor layer but also the gate insulating layer and the electrode may be formed by using a material which can be formed a film with the coating application.

The use of the inkjet printing apparatus to form the organic EL element portion of the organic EL display apparatus has conventionally been performed (for example, see Patent Document 1). When the inkjet printing apparatus is used for forming the organic transistor, however, a new problem to be solved arises since the transistor has a small area relatively to the organic EL element portion and a larger number of transistors are provided for each dot to result in a high-density arrangement.

[Patent Document 1] Japanese Patent Laid-Open No. 2002-222695

### DISCLOSURE OF THE INVENTION

### Problems to be Solved by the Invention

An inkjet printing apparatus for supplying a liquid material to a substrate includes a nozzle head having numerous discharge holes arranged regularly. The nozzle head scans in one direction to discharge and supply the liquid material onto the substrate at predetermined positions. Typically, the nozzle head has the discharge holes with equal pitches so as to support various patterns.

Many of the current nozzle heads of the inkjet printing apparatuses have discharge holes arranged in a line with pitches from several tens to several hundreds of micrometers. On the other hand, the organic EL display apparatuses have had higher resolutions and had smaller dot sizes year by year. For example, assuming that a 7-inch VGA panel is used, a dot size is approximately 225 μm by 75 μm when one pixel is divided into three sub-pixels having equal areas. The size is substantially equal to the pitch of the discharge holes in the inkjet apparatus.

For forming the organic semiconductor layer which is one of the components of the organic transistor with the coating application by using such a inkjet printing apparatus, the nozzle head may be inclined and scan such that the discharge holes pass over portions arranged on a substrate where organic transistors are to be formed, by way of example. In the past when the resolution was not very high yet, transistors were arranged at sufficiently large intervals relatively to the pitches of discharge holes formed in a nozzle head, so that no correlation was present between the placement of the organic transistors and the production efficiency. However, with a higher and higher resolution, it is now necessary to form a panel on which organic transistors are placed at smaller intervals. The problem of the production efficiency has become obvious as described below.

As schematically shown in FIG. 12 for example, assume that a plurality of dots 10 are formed on a substrate 1 and two transistors Tr1 and Tr2 are placed in one dot 10. To apply a coating of liquid material to both of the transistors Tr1 and Tr2, two approaches are possible. In a first approach, a nozzle head 12 having discharge holes 11 scans to apply a coating of the liquid material to the transistor Tr1 and then the nozzle head 12 again scans to apply a coating to the transistor Tr2. In a second approach, a coating is applied to the transistors Tr1 and Tr2 simultaneously in one scanning. In the former, since the nozzle head 12 should scan at least twice, the production efficiency is reduced. In the latter, the nozzle head 12 should be inclined at a large angle depending on the placement of the transistors and eventually should scan many times, leading to a reduction in production efficiency. The problem is particularly serious when the number of the organic transistors per dot is increased.

Problems to be solved by the present invention include the abovementioned one, for example. It is thus an object of the present invention to provide an organic EL display apparatus with improved production efficiency which has a dot formed at least of an organic EL element, a capacitor, and an organic transistor, has a display portion formed of a plurality of dots arranged on a substrate, and is active-driven, and to provide a manufacture method of the organic EL display apparatus.

### Means for Solving the Problems

According to an aspect, as described in claim 1, the present invention provides an organic EL display apparatus including a plurality of dots, each of the dots at least including an organic EL element, a capacitor, and an organic transistor, the display apparatus including a display portion formed of the dots arranged on a substrate, and the display apparatus being active-driven, wherein, when the shortest interval between the organic transistors in a channel length direction is represented as a, all of the organic transistors provided for the display portion are placed such that each of intervals between the organic transistors in the channel length direction is equal to an integral multiple of the interval a.

According to another aspect, as described in claim 7, the present invention provides a method of manufacturing an organic EL display apparatus including a plurality of dots, each of the dots at least including an organic EL element, a capacitor, and an organic transistor, the display apparatus including a display portion formed of the dots arranged on a substrate, and the display apparatus being active-driven, the method including the steps of, when the shortest interval between portions where the organic transistors are formed in a channel length direction is represented as a, preparing a substrate on which all of the portions where the organic transistors are formed in the display portion are placed at an interval in the channel length direction, the interval being equal to an integral multiple of the interval a, and inclining an inkjet nozzle having numerous arranged discharge holes formed therein at a predetermined angle to maximize the number of the discharge nozzles passing over the portions where the organic transistors are formed, and performing deposition by applying a coating of a liquid material of at least one of an organic semiconductor layer, a gate insulating film, and a gate electrode to the portions where the organic transistors are formed while the inkjet nozzle scans in a channel width direction.

### BRIEF DESCRIPTION OF DRAWINGS

FIG. 1 A schematic plan view showing a pixel constituting a display portion of an organic EL display apparatus according to Embodiment 1 of the present invention.

FIG. 2 A circuit configuration diagram of the organic EL display apparatus shown in FIG. 1.

FIG. 3 A schematic section view showing an organic EL element provided in the organic EL display apparatus shown in FIG. 1.

FIG. 4 A schematic section view showing an organic transistor provided in the organic EL display apparatus shown in FIG. 1.

FIG. 5 A flow chart showing a manufacture process of the organic EL display apparatus shown in FIG. 1.

FIG. 6A Schematic plan views each showing a manufacture step of the organic EL display apparatus shown in FIG. 1.

FIG. 6B Schematic plan views each showing a manufacture step of the organic EL display apparatus shown in FIG. 1.

FIG. 7 A schematic diagram showing an inclined nozzle head when organic transistors are placed at different intervals.

FIG. 8 A schematic plan view showing a pixel constituting a display portion of an organic EL display apparatus according to another embodiment of the present invention.

FIG. 9 A schematic plan view showing a pixel constituting a display portion of an organic EL display apparatus according to another embodiment of the present invention.

FIG. 10 A schematic plan view showing a pixel constituting a display portion of an organic EL display apparatus according to another embodiment of the present invention.

FIG. 11 A schematic plan view showing a pixel constituting a display portion of an organic EL display apparatus according to another embodiment of the present invention.

FIG. 12 A diagram for explaining a problem when an organic transistor is manufactured in an organic EL display apparatus by using an inkjet printing apparatus.

### DESCRIPTION OF REFERENCE NUMERALS

2 DISPLAY PORTION
3 SUBSTRATE
4A, 4B, 4C DOT
5A, 5B, 5C ORGANIC EL ELEMENT
6A, 6B, 6C ORGANIC TRANSISTOR
7A, 7B, 7C CAPACITOR
8 NOZZLE HEAD

### BEST MODE FOR CARRYING OUT THE INVENTION

A manufacture method of an organic transistor and the structure thereof according to preferred embodiments of the present invention will hereinafter be described in detail with reference to the accompanying drawings. However, the present invention is not limited to the embodiments described below.

### Embodiment 1

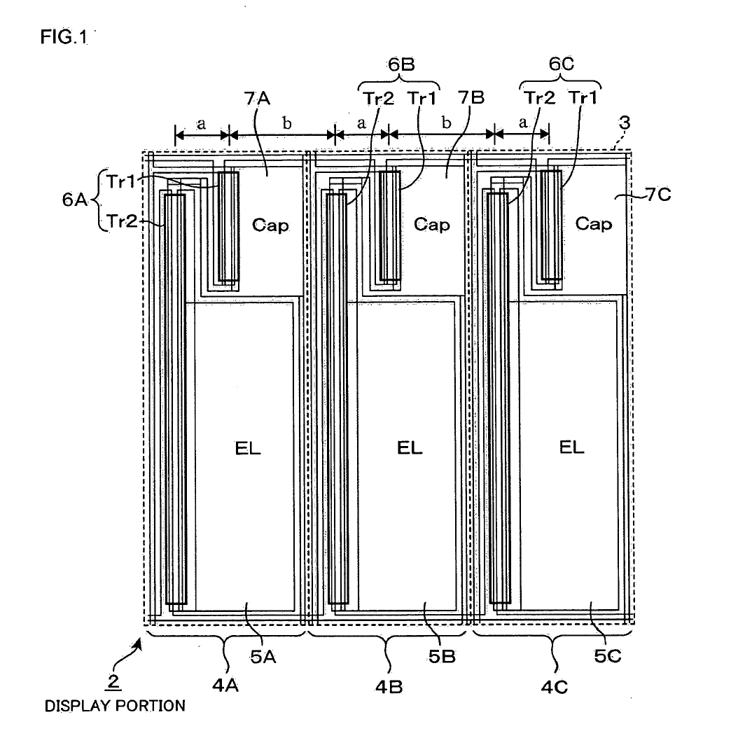

An organic EL display apparatus according to a preferred embodiment of the present invention will hereinafter be described in detail with reference to the accompanying drawings. FIG. 1 is a plan view schematically showing the organic EL display apparatus formed on a substrate.

A display portion 2 of the organic EL display apparatus is formed by arranging rectangular dots 4 in a matrix on a substrate 3. FIG. 1 shows, by way of example, three dots 4A, 4B, and 4C which emit light of red (R), green (G), and blue (B), respectively, formed on the substrate 3. In reality, numerous dots 4 are formed in the matrix on the single substrate 3.

Each of the dots 4 (4A, 4B, 4C) has an organic EL element 5 (5A, 5B, 5C) which forms a light-emitting portion, an organic transistor 6 (6A, 6B, 6C) for active-driving the organic EL element 5, and a capacitor 7 (7A, 7B, 7C). A first organic transistor Tr1 and a second organic transistor Tr2 for switching and driving are placed on each of the dots 4. In the example of FIG. 1, the second organic transistor Tr2 having a length substantially equal to a longer side of the dot 4 and the first organic transistor Tr1 having a length approximately one-third of the second organic transistor Tr2 are formed with a spacing therebetween in parallel with the longer side of the dot 4.

The first and second organic transistors Tr1 and Tr2 have the same basic structure in which a pair of source and drain electrodes is formed along its longitudinal direction and a channel is formed between the source and drain electrodes. Thus, in the present specification, the lateral direction of the dot 4 (horizontal direction of the sheet) is referred to as a “channel length direction” and the longitudinal direction of the dot 4 (vertical direction of the sheet) is referred to as a “channel width direction.” Of the spacing in the channel length direction between the first organic transistor Tr1 and the second organic transistor Tr2 (spacing between central lines) and the spacing between the first organic transistor Tr1 in the dot 4A and the second organic transistor Tr2 in the adjacent dot 4B, the shorter one is referred to as a spacing a and the longer one is referred to as a spacing b. The transistors are placed such that the spacing b is equal to an integral multiple of the spacing a (b=na, where n represents an arbitrary natural number). Preferably, n is equal to or smaller than three. More preferably, all of the organic transistors are placed such that the spacing in the channel length direction is an equal pitch (n=1). Assuming that a 7-inch VGA panel is used by way of example, a can be set to 25 μm and b can be set to 50 μm (n=2).

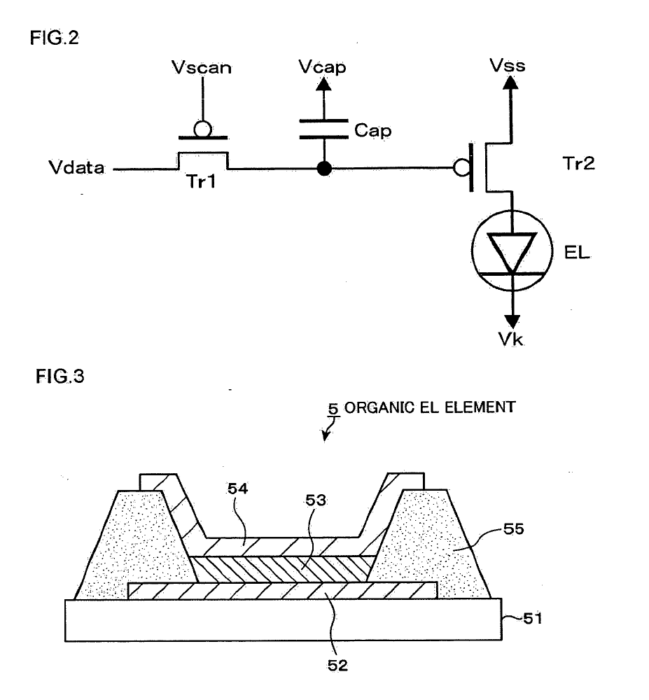

Each of the dots 4 (4A, 4B, 4C) having the abovementioned structure has a circuit configuration as shown in FIG. 2 and is active-driven, for example.

### (Organic El Element)

An example of the organic EL element 5 used in Embodiment 1 will be described with reference to FIG. 3. As shown in FIG. 3, the organic EL element 5 used in Embodiment 1 is formed to have an anode 52 serving as a lower electrode, an organic layer 53, and a cathode 54 serving as an upper electrode, all of which are stacked in order over a substrate 51. A bank (barrier portion) 55 having a normally tapered shape is formed on the substrate 51 to cover an end portion of the anode 53. The organic layer 53 and the cathode 54 are formed, for example with an evaporation method, such that an opening portion surrounded by the bank 55 serves as a light-emitting portion. The lower electrode may be provided as the cathode 54 and the upper electrode may be provided as the anode 52.

The substrate 51 can be formed by using a flat-plate substrate or a film substrate, for example, depending on the use of the element. Materials thereof can be selected as appropriate depending on the use of the element, and for example, a glass substrate or a plastic substrate may be selected. The anode 52 may be formed of a material having a high work function, and for example, it is possible to use a metal oxide such as ITO (Indium Tin Oxide) and IZO (Indium Zinc Oxide), a metal such as Cr, Mo, Ni, Pt, and Au or a compound thereof, or an alloy containing any of them. The cathode 54 may be formed of a material having a low work function, and for example, it is possible to use a metal such as Al or a compound thereof, or an alloy containing any of them.

Although not shown, the organic layer 53 is constituted of a multilayered film including a hole injection layer, a hole transfer layer, a light-emitting layer, and an electron injection layer, all of which are stacked in order from the side of the anode 52. Each of the hole injection layer and the hole transfer layer may be formed of a material having excellent hole transfer properties and, for example, a phthalocyanine compound such as copper phthalocyanine (Cu—Pc) can be used. It is essential only that the organic light-emitting layer should have the function of producing the electroluminescence phenomenon. For example, a fluorescent organic metal compound such as (8-hydroxyquinolinate)aluminum complex (Alq₃) can be used. The electron injection layer may be formed of a material having excellent electron injection properties. For example, a metal oxide such as lithium oxide (Li₂O) can be used. However, the materials and structures of the organic layer are not limited thereto and other known materials and structures may be used.

The bank 55 may be formed of a material having insulation, and it is preferable to use a resist which can be patterned with a photolithography method, for example.

For a color display, the organic layers 53 of the organic EL elements 5A, 5B, and 5C can be formed of materials which emit light of red (R), green (G), and blue (B), respectively. However, the present invention is not limited thereto, and white light can be color-converted through a color filter, for example.

### (Organic Transistor)

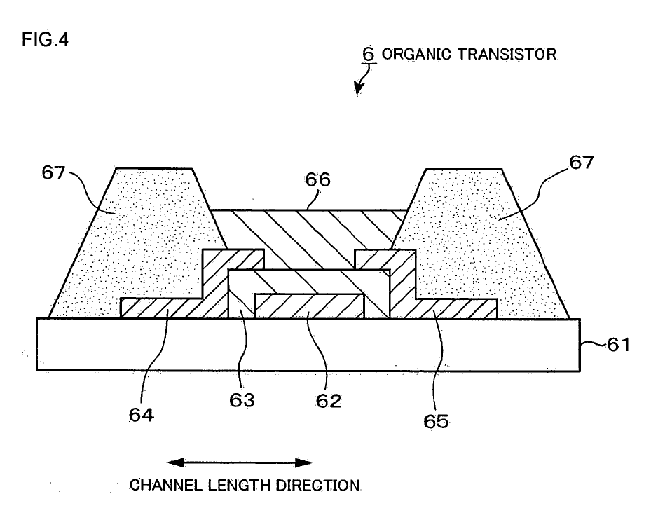

Next, an example of the organic transistor 6 used in Embodiment 1 will be described with reference to FIG. 4. As shown in FIG. 4, the organic transistor 6 used in Embodiment 1 has a gate electrode 62, a gate insulating film 63, a pair of a source electrode 64 and a drain electrode 65, all of which are stacked in order on a substrate 61. A bank (barrier portion) 67 is formed to have an opening portion in an area where an organic semiconductor layer 66 is to be formed, that is, to have the opening portion in the area where a channel is to be formed. The organic semiconductor layer 66 is formed by applying a coating of liquid material to the inner area surrounded by the bank 67. While FIG. 4 shows the organic transistor of a bottom contact type by way of example, the present invention is not limited thereto, and an organic transistor of a top contact type or a top gate type may be used.

The substrate 61 can be formed, for example, by using a flat-plate substrate or a film substrate depending on the use of the element. Materials thereof can be selected as appropriate depending on the use of the element, and for example, a glass substrate or a plastic substrate can be selected. The gate electrode 62, the source electrode 64, and the drain electrode 65 may be formed of a material having conductivity, and for example, it is possible to use a metal alone such as Ta, Cu, Au, Pt, Au, W, Ru, Ir, Al, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, and Lu, a stack of any of the metals, or a compound thereof. It is also possible to use a metal oxide such as ITO and IZO, or an organic conductive material including a conjugate polymer compound such as polyaniline, polythiophene, and polypyrrole.

The gate insulating film 63 may be formed of a material having insulation, and for example, it is possible to use a metal oxide such as LiOx, LiNx, NaOx, KOx, RbOx, CsOx, BeOx, MgOx, MgNx, CaOx, CaNx, SrOx, BaOx, ScOx, YOx, YNx, LaOx, LaNx, CeOx, PrOx, NdOx, SmOx, EuOx, GdOx, TbOx, DyOx, HoOx, ErOx, TmOx, YbOx, LuOx, TiOx, TiNx, ZrOx, ZrNx, HfOx, HfNx, ThOx, VOx, VNx, NbOx, TaOx, TaNx, CrOx, CrNx, MoOx, MoNx, WOx, WNx, MnOx, ReOx, FeOx, FeNx, RuOx, OsOx, CoOx, RhOx, IrOx, NiOx, PdOx, PtOx, CuOx, CuNx, AgOx, AuOx, ZnOx, CdOx, HgOx, BOx, BNx, AlOx, AlNx, GaOx, GaNx, InOx, TiOx, TiNx, SiNx, GeOx, SnOx, PbOx, POx, PNx, AsOx, SbOx, SeOx, and TeOx, a metal compound oxide such as LiAlO₂, Li₂SiO₃, Li₂TiO₃, Na₂Al₂₂O₃₄, NaFeO₂, Na₄SiO₄, K₂SiO₃, K₂TiO₃, K₂WO₄, Rb₂CrO₄, Cs₂CrO₄, MgAl₂O₄, MgFe₂O₄, MgTiO₃, CaTiO₃, CaWO₄, CaZrO₃, SrFe₁₂O₁₉, SrTiO₃, SrZrO₃, BaAl₂O₄, BaFe₁₂O₁₉, BaTiO₃, Y₃A₁₅O₁₂, Y₃Fe₅O₁₂, LaFeO₃, La₃Fe₅O₁₂, La₂Ti₂O₇, CeSnO₄, CeTiO₄, Sm₃Fe₅O₁₂, EuFeO₃, Eu₃Fe₅O₁₂, GdFeO₃, Gd₃Fe₅O₁₂, DyFeO₃, Dy₃Fe₅O₁₂, HoFeO₃, Ho₃Fe₅O₁₂, ErFeO₃, Er₃Fe₅O₁₂, Tm₃Fe₅O₁₂, LuFeO₃, Lu₃Fe₅O₁₂, NiTiO₃, Al₂TiO₃, FeTiO₃, BaZrO₃, LiZrO₃, MgZrO₃, HfTiO₄, NH₄VO₃, AgVO₃, LiVO₃, BaNb₂O₆, NaNbO₃, SrNb₂O₆, KTaO₃, NaTaO₃, SrTa₂O₆, CuCr₂O₄, Ag₂CrO₄, BaCrO₄, K₂MoO₄, Na₂MoO₄, NiMoO₄, BaWO₄, Na₂WO₄, SrWO₄, MnCr₂O₄, MnFe₂O₄, MnTiO₃, MnWO₄, CoFe₂O₄, ZnFe₂O₄, FeWO₄, CoMoO₄, CuTiO₃, CuWO₄, Ag₂MoO₄, Ag₂WO₄, ZnAl₂O₄, ZnMoO₄, ZnWO₄, CdSnO₃, CdTiO₃, CdMoO₄, CdWO₄, NaAlO₂, MgAl₂O₄, SrAl₂O₄, Gd₃Ga₅O₁₂, InFeO₃, MgIn₂O₄, Al₂TiO₅, FeTiO₃, MgTiO₃, Na₂SiO₃, CaSiO₃, ZrSiO₄, K₂GeO₃, Li₂GeO₃, Na₂GeO₃, Bi₂Sn₃O₉, MgSnO₃, SrSnO₃, PbSiO₃, PbMoO₄, PbTiO₃, SnO₂—Sb₂O₃, CuSeO₄, Na₂SeO₃, ZnSeO₃, K₂TeO₃, K₂TeO₄, Na₂TeO₃, and Na₂TeO₄, a sulfide such as FeS, Al₂S₃, MgS, and ZnS, a fluoride such as LiF, MgF₂, and SmF₃, a chrolide such as HgCl, FeCl₂, and CrCl₃, a bromide such as AgBr, CuBr, MnBr₂, an iodide such as PbI₂, CuI, and FeI₂, or a metal oxynitride such as SiAlON. It is possible to use a polymer material such as a polyimide, polyamide, polyester, polyacrylate, epoxy resin, phenole resin, and polyvinylalcohol. It is also possible to use an organic-inorganic hybrid material.

The bank 67 may be formed of a material having insulation, and for example, it is preferable to use a resist which can be patterned with the photolithography method. Specifically, it is preferable to use a material having repellency to the liquid material applied to the inner area surrounded by the bank 67, for example a resist containing a fluorine component.

The organic semiconductor layer 66 may be formed of an organic material exhibiting semiconductor properties. For example, it is possible to use a polymer material such as an aromatic conjugated polymer including polyparaphenylene, an aliphatic conjugated polymer including polyacetylene, a heterocyclic conjugated polymer including polypinole and polythiophene, a heteroatom-containing conjugated polymer including polyaniline and polyphenylene sulfide, and a composite conjugated polymer having a structure of alternately bonded constituent units of a conjugated polymer including poly(phenylenevinylene), poly(arylenevinylene) and poly(thienylenevinylene). It is also possible to use a polymer including alternate chains of oligosilane and a carbon-based conjugated structure such as polysilane and a disilanylene carbon-based conjugated polymer structure including a disilanylene arylene polymer, a (disilanylene) ethenylene polymer, and a (disilanylene) ethynylene polymer. It is also possible to use a polymer chain including an inorganic element containing phosphorous or nitrogen, a polymer containing a coordinated aromatic ligand of a polymer chain such as phthalocyanate polysiloxane, a polymer containing ring-fused perylene with thermal treatment such as perylenetetracarboxylic acid, a ladder polymer obtained by thermally treating a polyethylene derivative containing a cyano group such as polyacrylonitrile, and a composite material containing an intercalated organic compound in perovskite. In addition, it is possible to use a material of low molecular weight soluble in a solvent by adding a functional group, among a phthalocyanine derivative, a naphthalocyanine derivative, an azo compound derivative, a perylene derivative, an indigo derivative, a quinacridone derivative, a polycyclic quinone derivative such as anthraquinone, a cyanine derivative, a fullerene derivative, or a nitrogen-containing cyclic compound derivative such as indole, carbazole, oxazole, inoxazole, thiazole, imidazole, pyrazole, oxaadiazole, pyrazoline, and triazole, a hydrazine derivative, a triphenylamine derivative, a triphenylmethane derivative, stilbene, a quinone compound derivative such as anthraquinone diphenoquinone, and a polycyclic aromatic compound derivative such as anthracene, bilene, phenanthrene, and coronene.

### (Capacitor)

The capacitor 7 has the structure in which a dielectric film is sandwiched between an upper conductive material and a lower conductive material. The dielectric may be a material having insulation, and it is possible to use the same material as that of the gate insulating film 63. The conductive material may be the same material as that of the gate electrode 62, the source electrode 64, or the drain electrode 65.

### (Manufacture Method)

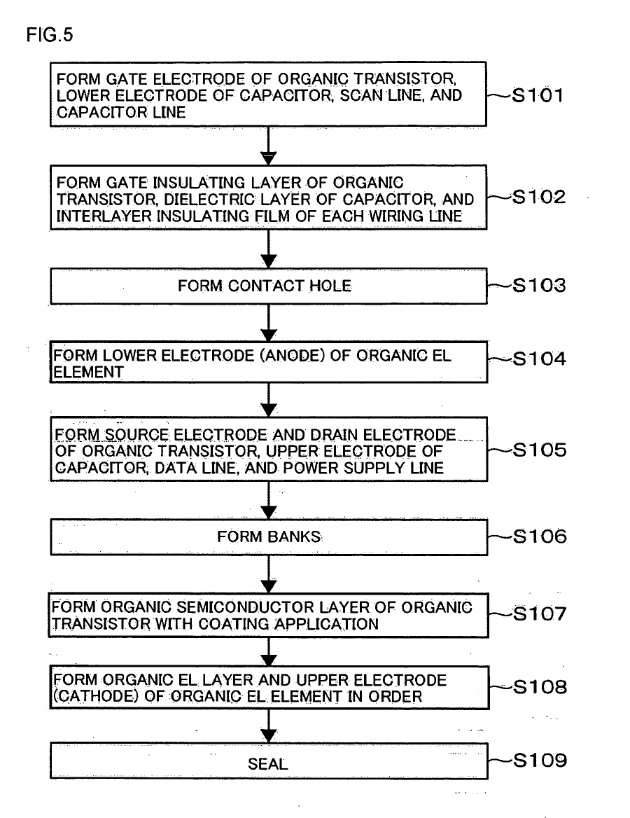

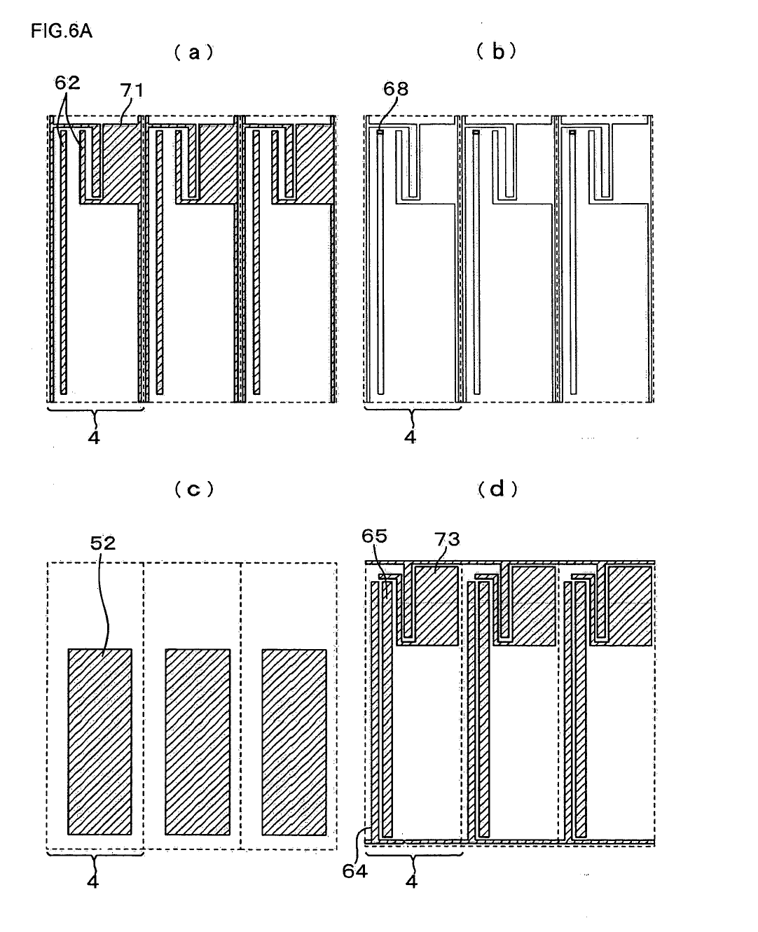

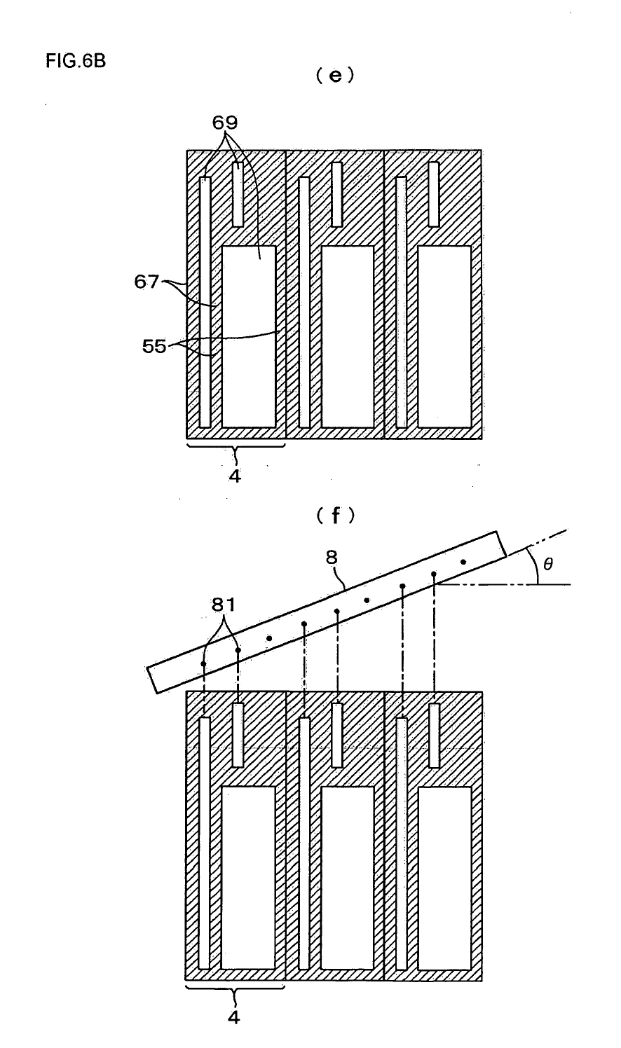

Next, a method of manufacturing the organic EL display apparatus having the structure shown in FIG. 1 will be described with reference to FIGS. 5 and 6. FIG. 5 is a flow chart. FIGS. 6A and 6B are schematic plan views showing the organic EL display apparatus at each step.

First, as shown at step S101 in FIG. 5, the gate electrode 62 of the organic transistor 6, a lower electrode 71 of the capacitor 7, a scan line, and a capacitor line are formed on the substrate 3 (substrate 51, 61). Specifically, a conductive thin film of tantalum (Ta) or the like is formed with a sputtering method, and then a photoresist is used to form a mask patterned in a predetermined shape with the photolithography method, by way of example. Reactive ion etching, for example, is performed through the mask to provide the conductive thin film corresponding to the gate electrode 62 of the organic transistor 6, the lower electrode 71 of the capacitor 7, the scan line, and the capacitor line simultaneously (FIG. 6A(a)).

After the mask is removed, as shown at step S102 in FIG. 5, oxidation is performed such as anodic oxidation on the surface of the patterned conductive thin film to form an oxidized film such as tantalum pentoxide (Ta₂O₅) on the surface of the conductive thin film (see FIG. 6A(a)). The oxidized film serves as the gate insulating film 63 of the organic transistor 6, a dielectric film 72 of the capacitor 7, and an interlayer insulating film for each wiring line. The formation of the film serving as the insulating film is not limited to the oxidation, and the film may be formed with sputtering, CVD, or a coating application process.

Then, as shown at step S103 in FIG. 5, a contact hole 68 to the gate electrode 62 is formed (FIG. 6A(b)). The contact hole 68 can be provided by forming a mask in a predetermined shape with the photolithography method and then etching the gate insulating film 63 through the mask, for example.

Next, as shown at step S104 in FIG. 5, a conductive thin film of ITO or the like which allows light transmission is formed with the sputtering method, for example. A photoresist is used to form a mask in a predetermined shape with the photolithography, and patterning is performed with etching to form the anode 52 of the organic EL element 5 (FIG. 6A(c)).

Then, as shown at step S105 in FIG. 5, the source electrode 64 and the drain electrode 65 of the organic transistor 6, an upper electrode 73 of the capacitor 7, a data line, and a power supply line are formed. Specifically, a conductive thin film constituting a stacked film of Cr and Au is deposited with the sputtering method, and then a photoresist is used to form a mask patterned in a predetermined shape with the photolithography method, for example. Etching is performed through the mask to form the conductive thin film corresponding to the source electrode 64 and the drain electrode 65 of the organic transistor 6, the upper electrode 73 of the capacitor 7, the data line, and the power supply line simultaneously (FIG. 6A(d)).

Next, as shown at step S106 in FIG. 5, the bank 67 and the bank 55 are simultaneously formed (FIG. 6B(e)) such that the bank 67 has the opened area (opening portion 69) where the organic semiconductor layer 66 of each of the first and second organic transistors Tr1 and Tr2 is to be formed, and that the bank 55 has the opened area (opening portion 69) where the organic EL element 5 is to be formed. As a specific manufacture method thereof, a fluorine-containing resist is deposited with spin coating and then patterned with the photolithography method, for example. To prevent a short circuit between the anode 52 and the cathode 54 of the organic EL element 5, the bank 55 is preferably patterned so as to cover the end portion of the anode 52.

Then, as shown at S107 in FIG. 5, a coating of the organic semiconductor material of the organic transistor 6 is applied to the inner area of the bank 67 to form the organic semiconductor layer 66. Specifically, as shown in FIG. 6B(f), a nozzle head 8 of an inkjet printing apparatus is placed outside the substrate 3 and inclined (at an inclination angle θ) such that some of a plurality of discharge holes 81 formed with equal pitches pass over the organic transistor 6. The nozzle head 8 scans in the channel width direction to apply a coating of the organic semiconductor material, for example poly-3-hexylthiophene (P3HT), to the inner area surrounded by the bank 67 of each of the organic transistors 6. If necessary, the nozzle head 8 scans a plurality of times to complete the formation of the organic semiconductor layers 66 of all of the organic transistors 6 ultimately.

Next, as shown at step S108 in FIG. 5, the organic layer 53 of the organic EL 5 is formed with vacuum evaporation, and then the cathode 54 serving as the upper electrode is formed through evaporation. Next, as shown at step S109 in FIG. 5, the structure is sealed with a glass can, for example.

According to Embodiment 1 described above, when the shortest interval between the organic transistors 6 in the channel length direction is represented as a, all of the organic transistors provided in the display portion are placed such that the interval between the organic transistors in the channel length direction is equal to an integral multiple of a. It is thus possible to minimize the number of unused discharge holes which are not involved in the discharge operation. As a result, the production efficiency can be improved.

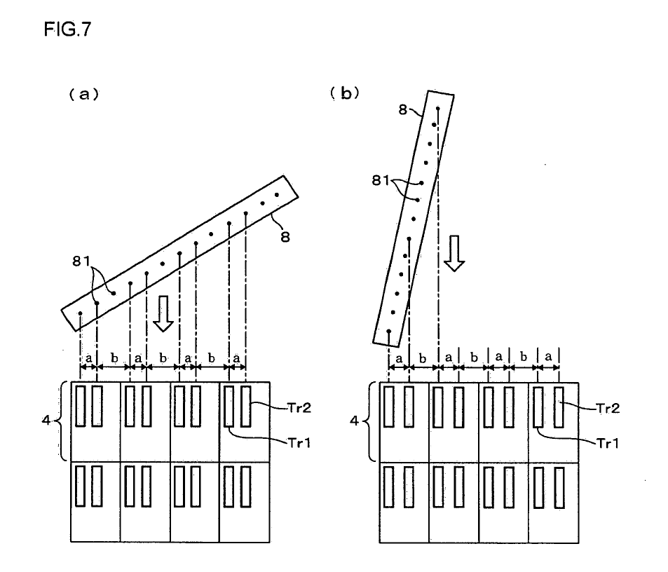

Specifically, in view of the placement of the two organic transistors Tr1 and Tr2 in one dot, when the intervals between the transistors on the display portion 2 are represented as a and b (a≦b), the production efficiency is improved if all of the organic transistors are placed at intervals equal to any integral multiple of a (b=na) rather than intervals a and b selected randomly. For example, when the difference in effects is examined in the structure shown in FIG. 7(a) in which the transistors are arranged at intervals represented as b=2a and the structure shown in FIG. 7(b) in which the transistors are arranged at intervals represented as b=(7/5)a, the nozzle head 8 is inclined as shown in each of FIGS. 7(a) and 7(b). It can be seen that the number of unused discharge holes 81 is smaller and higher production efficiency is achieved in FIG. 7(a) in which the intervals are set to the integral multiple.

The production efficiency is higher as n is smaller. The nozzle head 8 of the inkjet printing apparatus may not discharge droplets straight in some cases due to the surface tension of the liquid and the limited manufacturing accuracy of the apparatus. To address this, in Embodiment 1, the bank 67 having liquid repellency is formed. Even when the droplets are applied to a somewhat shifted position, they are eventually placed in the predetermined position as long as they fall into the inner area of the bank 67. If the interval between the organic transistors is extremely small, the droplets inevitably flow into the inner area of the bank of the adjacent organic transistor to cause a failure such as variations in film thickness between the transistors. This problem, however, can be solved by reducing n. Preferably, n is equal to or smaller than three, and most preferably, n is equal to one.

Even when each of the organic transistors is somewhat displaced from the position where the abovementioned conditions are satisfied, the repellency of the bank 67 can achieve the same effects as those described above. Assuming that the length of one pixel formed by the dot in the channel length direction is represented as L, the accuracy of the placement position of each organic transistor in the channel length direction preferably falls within ±L/200. By way of example, when a 7-inch VGA panel is used, the tolerance is ±1.1 m.

While Embodiment 1 has been described in conjunction with the example of the organic semiconductor layer 66 deposited through the coating application, the present invention is not limited thereto. When a liquid material is used as the material of the gate insulating film 63 and/or the gate electrode 62, they can be deposited through the coating application similarly. In this case, the production efficiency can also be improved.

Next, another embodiment of the present invention will be described.

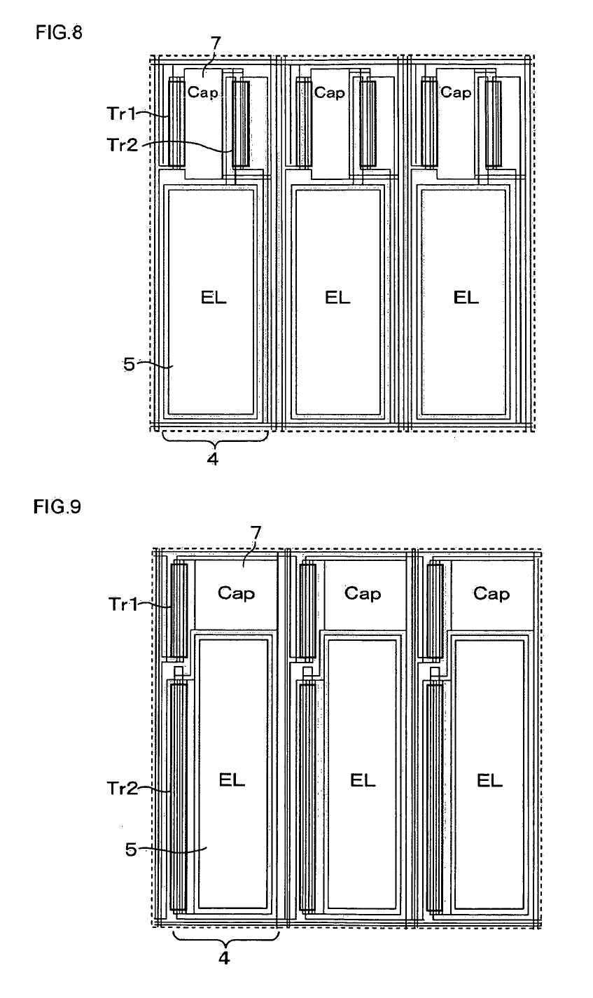

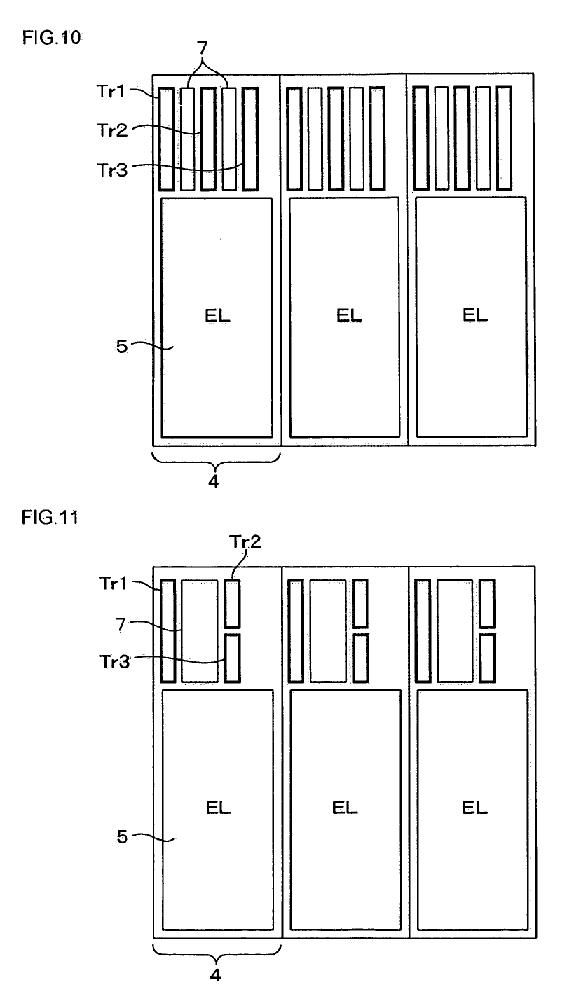

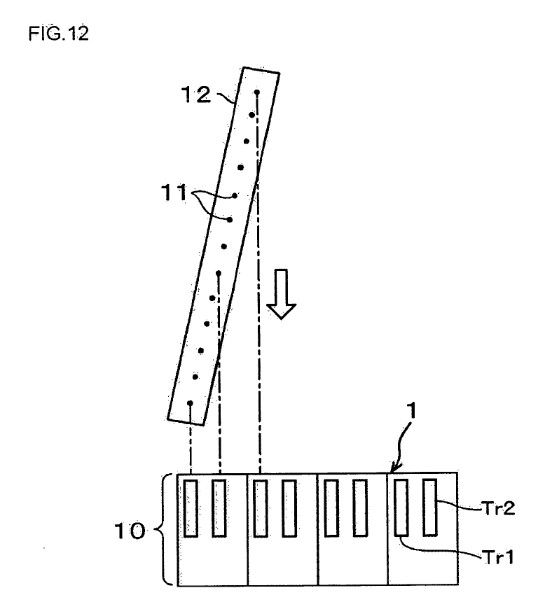

In FIG. 1, the first and second organic transistors Tr1 and Tr2 having the different lengths are placed at the intervals equal to the integral multiple, but the present invention is not limited thereto. As shown in FIG. 8, all of transistors may have the same length, or may be arranged at equal intervals in a channel length direction. Alternatively, as shown in FIG. 9, transistors within a dot may be arranged in a line in a channel width direction. In addition, the number of the organic transistors provided for one dot is not necessarily two, and three or more organic transistors may be provided. In this case, as shown in FIG. 10, the transistors may be arranged in a channel length direction within a dot, or as shown in FIG. 11, the transistors may be arranged in a channel length direction and a channel width direction. In other words, any structure can achieve the same effects as those in Embodiment 1 described above as long as the structure satisfies the condition that all of the organic transistors provided in the display portion are placed such that each of the intervals between the transistors in the channel length direction is equal to an integral multiple of the interval a which represents the shortest interval between the organic transistors in the channel length direction. In addition, when the condition is satisfied, a stacked structure may be used in which the organic EL element 5 is placed above the organic transistor 6.

1. An organic EL display apparatus comprising a plurality of dots, each of the dots at least including an organic EL element, a capacitor, and an organic transistor, the display apparatus including a display portion formed of the dots arranged on a substrate, and the display apparatus being active-driven,
wherein, when a shortest interval between the organic transistors in a channel length direction is represented as a, all of the organic transistors provided for the display portion are placed such that each of intervals between the organic transistors in the channel length direction is equal to an integral multiple of the interval a.

2. The organic EL display apparatus according to claim 1, wherein all of the organic transistors in the display portion are placed such that the intervals between the organic transistors in the channel length direction are equal.

3. The organic EL display apparatus according to claim 1, wherein at least two or more organic transistors are placed with an interval therebetween in the channel length direction or in a channel width direction in each of the dots.

4. The organic EL display apparatus according to claim 1, wherein, in the organic transistor, at least one of an organic semiconductor layer constituting a channel portion, a gate insulating film, and a gate electrode is formed with coating application of a liquid material.

5. The organic EL display apparatus according to claim 4, wherein a bank having an opening portion at least in an area where a coating of the liquid material is applied is formed over the substrate.

6. The organic EL display apparatus according to claim 5, wherein, when a length of one pixel formed by the dot in the channel length direction is represented as L, accuracy of a placement position of each of the organic transistors in the channel length direction falls within ±L/200.

7. A method of manufacturing an organic EL display apparatus comprising a plurality of dots, each of the dots at least including an organic EL element, a capacitor, and an organic transistor, the display apparatus including a display portion formed of the dots arranged on a substrate, and the display apparatus being active-driven, the method comprising the steps of:
when a shortest interval between portions where the organic transistors are formed in a channel length direction is represented as a, preparing a substrate on which all of the portions where the organic transistors are formed in the display portion are placed at an interval in the channel length direction, the interval being equal to an integral multiple of the interval a; and
inclining an inkjet nozzle having numerous arranged discharge holes formed therein at a predetermined angle to maximize the number of the discharge nozzles passing over the portions where the organic transistors are formed, and performing deposition by applying a coating of a liquid material of at least one of an organic semiconductor layer, a gate insulating film, and a gate electrode to the portions where the organic transistors are formed while the inkjet nozzle scans in a channel width direction.

8. The method of manufacturing an organic EL display apparatus according to claim 7, wherein all of the portions where the organic transistors are formed in the display portion are placed such that the intervals between the portions where the organic transistors are formed in the channel length direction are equal.

9. The method of manufacturing an organic EL display apparatus according to claim 7, wherein a bank having an opening portion surrounding an area where the coating of the liquid material is applied is formed over the substrate before the coating application of the liquid material.

10. The method of manufacturing an organic EL display apparatus according to claim 9, wherein, when a length of one pixel formed by the dot in the channel length direction is represented as L, accuracy of a placement position of each of the organic transistors in the channel length direction falls within ±L/200.
